(19) United States
(12) Patent Application Publication
(10) Pub. No.: US 2002/0022364 A1
(43) Pub. Date: Feb. 21, 2002

(54) Method for producing a metal film, a thin film device having such metal film and a liquid crystal display device having such thin film device

(76) Inventors: Yoshihisa Hatta, Kobe-shi (JP); Akinori Matsumoto, Kobe-shi (JP); Shinichi Li, Kakogawa-shi (JP)

Correspondence Address: U.S. Philips Corporation, 580 White Plains Road, Tarrytown, NY, 10591, US

(21) Appl. No.: 09/929,116

(22) Filed: Aug. 14, 2001

(30) Foreign Application Priority Data
Aug. 16, 2000 (JP) 2000-246994

(51) Int. Cl. H01L 21/44

(52) U.S. Cl. 438/673

(57) ABSTRACT

The invention provides a method for forming a metal film for a thin film device so as to have certain gentle taper angles. The method is an improved fine work method to produce metal films such as light shutter films for thin film devices through the combined production method of a wet-etching step and a dry-etching step. Preliminarily, the cross sectional shape of the resist film is formed so as to have certain taper angles at both end portions. Accordingly, during the dry-etching step, an etchant gas can smoothly flow through along the sidewall of the resist and accordingly the metal film can be formed so as to have gentle taper angles along the flow line of the etchant gas. Thus, it is possible in accordance with the invention to significantly improve the production efficiency and the quality of such thin film devices as the TFTs to be used for the LCDs.

### TECHNICAL FIELD

The invention relates to a method for producing metal films and, in particular, an improved method for producing such metal films as light shutter films, which are to be incorporated in thin film transistors within a liquid crystal display device.

### BACKGROUND OF THE INVENTION

In recent years, the demand for liquid crystal display devices (LCD) has been increasing in accordance with the common usage of computer displays, digital cameras, portable telephones, car-navigation devices and so on. In order to drive pixels of the active matrix type of LCD that is the majority of such LCDs, thin film transistors (TFT), which are thin film devices as active elements for the LCDs, are particularly required. Thus, in order to meet the strong demand for the LCDs, it is a key challenge in the art to increase the efficiency of producing the TFTs and also to improve their quality.

As for the TFTs used in the LCDs, there are two types of TFTs, a bottom-gate type and a top-gate type, both of which contain metal films to be used for wiring members and/or light shutter films. The Japan Patent Application NO. 1997-263974 discloses a production process (a fine metal work technique) for forming a metal light shutter film so as to increase the efficiency of producing the latter type (top-gate type) of the TFT and improve its quality. Following will briefly explain the fine metal work technique disclosed in the above-referenced patent application.

Referring to FIG. 12 (a) as a plan view and FIG. 12 (b) as a cross-section view, an array substrate 100 comprising the top-gate type of TFT elements is shown. As illustrated, gate electrodes (Y electrodes) 101 and data electrodes (X electrodes) 102 are disposed in a matrix manner on the array substrate 100, and TFTs 103 are located at intersectional points of the electrodes. Besides, sub-pixel electrodes 104 comprising transparent conductive films (ITO) 104 are connected to source electrodes (or drain electrodes) 105 of the TFTs 103 and electrodes for capacitors Cs 106 for accumulating the data are located in a part (approximately in the center in FIG. 12) of the sub-pixel electrodes 104. In the periphery of the array substrate 100, there provided pad electrodes 101′, 102′ that are connected with external devices (e.g., electronic circuits) so that sub-pixel electrodes 104 can be interfaced with such external devices to communicate data and control signals.

Referring to FIG. 12 (b), following will explain the cross-sectional structure of one unit among a plurality of units, each of which comprises a TFT element 103, a sub-pixel electrode 104 and a data accumulating capacitor Cs 106 that are disposed upon the array substrate 100. In order to construct the basic cross-sectional structure of the top-gate type of the LCD as illustrated in FIG. 12 (b), a light shutter film 108, which is a Cr metal film, is first formed on the glass substrate 107 and then an insulation layer SiOx 109 is formed on the light shutter film 108. Then a drain electrode 110 and a source electrode 111 are formed through ITO on the insulation layer SiOx 109. Besides, N⁺a-Si layer 112, which contains N⁺ as an impurity constituent to reduce the bonding resistance, is formed on the drain electrode 110 and the source electrode 111 and thereupon αSi layer 113 and SiNx layer 115 are formed, on which a gate electrode 113 comprising, for example, molybdenum tantalum (MoTa) is further formed. Finally, a protection film 114 comprising a nitrification material (SiNx) is formed on the gate electrode 113 so as to protect the a—Si layer 112, the gate electrode 113 and the SiNx layer 115. It should be noted that the protection layer 114 is not necessarily prerequisite, but rather not necessary if the SiNx exists above the layer corresponding to the ITO because any SiNx material remaining on pixels may cause some burnout problem on the pixel that would be displayed for a certain consecutive time period. In this way, one unit of TFT is formed on the array substrate 100. A display part (not shown herein) of the LCD incorporating the active matrix type of the TFTs is built up by bonding the array substrate (TFT substrate) 100 with an opposite substrate (not shown herein) having common electrodes in such manner as they are sandwiching the liquid crystal. Within the array substrate, a series of the TFT are located on the matrix of display electrodes. Respective opposite parts between the display electrode and the common electrode form a pixel capacity with the liquid crystal as an dielectric layer and will be serially selected by the TFT to be charged with a proper voltage. The charged voltage against the pixel capacity may be maintained by the OFF resistance of the TFT for a time period of one field unit. Liquid crystals have a characteristic of electrooptic anisotropy, so that the amount of transmitted lights may be finely adjusted according to the strength of the electric field formed by the pixel capacity. Thus a color distribution in which respective transmission rates are controlled for each pixel may pass through each color filter of the RGB, and as a result the desired image can be seen according to the principle of additive mixture of color stimuli on the display screen of the LCD.

Now the method for forming the Cr metal film 108 in accordance with the above-referenced patent application will be briefly introduced in conjunction with FIG. 13 (a), (b) and (c). At first, as illustrated in FIG. 13 (a), a Cr metal film with a thickness of about 1,500 angstrom is formed on the glass substrate 1 by means of spattering and then a resist film R is formed above the metal film. Thereafter, a desired pattern is developed by means of a known photolithography method.

As a next process, the portion of the Cr metal film 2 that extends outside below the portion covered by the resist R is removed using an appropriate etchant so that the resulting pattern of the Cr metal film 2 might be the same with that of the resist R as illustrated in FIG. 13 (b). With this process, in particular, such etched sidewalls of the Cr metal film 2 may be formed in a perpendicular shape as seen in FIG. 13 (b).

Furthermore, as illustrated in FIG. 13 (c), an RIE (reactive ion etching) process using an etchant gas comprising, for example, mixed gas of oxygen and either Cl₂ or HCl is performed on the resist R so as to be etched with the oxygen. Then another etching process using the same mixed gas is performed on the sidewalls of the Cr metal film 2 that has remained below the resist R. When this etching process is performed, predetermined etching conditions such as the plasma power, the mixture ratio of Cl₂ and O₂, the mixture ratio of HCl and O₂, the time for etching and so on are appropriately set. Thus, during the etching process, since the upper side of the Cr metal film 2 is first etched, the rate of the etching removal for the upper portion of the Cr metal may be promoted with the etching removal for the resist R, which may be resulted in the higher rate of the etching removal for the upper portion of the Cr metal film 2 than that for the lower portion of the Cr metal film 2 that is located more closely to the substrate 1. As a result, the sidewalls of the metal film 2 in terms of the cross-sectional view are formed in taper shape with a taper angle Rβ. As a result, the metal film 2 having the taper angle 2α is formed as illustrated in FIG. 13 (d). Note that the term “taper angle” in this application refers to a contacting angle of the end portion of the sidewalls of the film relative to the plane in terms of the perpendicular cross-sectional view when the concerned film is deposited on the concerned plane.

As might be recognized, this taper angle 2a of the metal film 2 may have a significant effect on the coverage of the upper layer covering the upper portion of the metal film 2. For example, in the case where the SiOx film 109 is formed on the metal film 2 as illustrated in FIG. 12 (b), the larger taper angle 2α (that is, the more upright sidewalls of the metal film 2), the thiner insulation SiOx film 109 along the edge of the metal film 2. As a result, a so-called step discreteness may occur at the step portion of the drain/source electrodes when they are formed above such SiOx film, which may be further resulted in a problem of the degraded display quality. Therefore, it is required to control the taper angle 2α so as to be always kept within less than a certain moderate angle to improve the quality, stability and yield of such thin film devices as TFTs for the LCDs.

However, for the method illustrated in FIG. 13 (a), (b) and (c), it is difficult to exactly control the taper angle Rβ in conjunction with the resist R and accordingly difficult to exactly form the taper angle 2α of the metal Cr film 108 below the resist because of the following reason. In the referenced dry-etching method, after the resist R has been formed in a trapezoid shape (with a taper angle Rβ) in terms of a cross-sectional view by downwardly applying the dry-etching with a given mixed gas, the Cr metal film 2 that lays below the resist R is etched. During the process to form the taper angle Rβ, the mixed gas tends to flow rather horizontally after it hits the upper plane of the resist R but may not go through to form the taper angle. Accordingly, it needs a longer etching time to form the taper angle, and furthermore it is not easy to keep a constant taper angle Rβ under the influence of the variation of the etching conditions due to the mixed gas, and the taper angle 2α may vary significantly according to the variation of the taper angle Rβ.

Therefore, the invention provides a method for precisely producing metal films such as metal light shutter films to be used in thin film devices. The invention especially provides an improved production method with a combination of a wet-etching process and a dry-etching process. In particular, the inventive method is to preliminarily provide both end portions of the cross section of the resist film so as to have a certain gentle taper angle and also form the cross section of the resist film in an arc shape wherein its bottom portion represents a bow shape. With such arrangement, during the dry-etching process, the etchant gas can smoothly flow through along with the resist sidewalls, so that the metal film can be always formed so as to have a certain gentle taper angle in accordance with such gas flow. Thus, it is the first objective of the invention to provide a production method for constantly forming metal films having certain gentle taper angle.

Beside, since the resist film has been formed in an arc shape beforehand, almost of the metal portion that should have been otherwise removed in the conventional dry-etching process would have been already removed. Accordingly, it is possible to reduce metal particles that may appear with the dry etching responsive chamber because the metal portion to be etched during the subsequent dry-etching process is already significantly reduced. This means reducing the cleaning cycles for the inside of the chamber as well as reducing significantly the possibility of the metal particles that may be mixed into the thin film devices to be produced. Thus, it is the second objective of the invention to provide a production method to significantly improve the production efficiency and the quality of such thin film devices as TFTs used for the LCDs.

### SUMMARY OF THE INVENTION

The invention provides a method for producing a metal film, the method comprising a first step for depositing a metal film on the surface of a given substrate, a second step for coating a resist material on the metal film to form a resist film, a third step for forming a resist pattern of the resist film by means of a photolithographic method, a fourth step for performing a wet-etching on the portion of the metal film that is not covered by the resist film, a fifth step for performing an oxygen-ashing on the resist pattern of the resist film, a sixth step for performing a dry-etching so as to form taper shapes on both end portions of the cross section of the metal film and a seventh step for removing the resist pattern. In the inventive method, during the second step, the resist film is formed in such way that both end portions of the cross section of the resist film have certain taper angles, and during the fifth step, the oxygen-ashing on the resist pattern is performed so that the metal film is exposed at both end potions of the cross section of the resist pattern. Thus, the invention can achieve the above-mentioned first and second objectives.

### BRIEF DESCRIPTION OF THE DRAWINGS

FIG. 1 is a schematic cross section illustrating a process of the production method in accordance with the embodiment of the invention;

FIG. 2 is a schematic cross section illustrating a process of the production method in accordance with the embodiment of the invention;

FIG. 3 is a schematic cross section illustrating a process of the production method in accordance with the embodiment of the invention;

FIG. 4 is a schematic cross section illustrating a process of the production method in accordance with the embodiment of the invention;

FIG. 5 is a schematic cross section illustrating a process of the production method in accordance with the embodiment of the invention;

FIG. 6 is a schematic cross section illustrating an etching process with a resist pattern having steep taper angles;

FIG. 7 is a schematic cross section illustrating an etching process with a resist pattern having gentle taper angles;

FIG. 8 is a graphical chart illustrating a relationship between the resist pre-baking temperature and the resist taper angle;

FIG. 9 is a graphical chart illustrating a relationship between the resist exposure amount and the resist taper angle;

FIG. 10 is a graphical chart illustrating a relationship between the resist development time and the resist taper angle;

FIG. 11 is a graphical chart illustrating a relationship between the resist post-baking temperature and the resist taper angle;

FIG. 12 is a plan view (a) and a cross-section view (b) to illustrate a basic structure of a top-gate type of TFT; and

FIG. 13 is a schematic cross section illustrating a metal film production method in accordance with the conventional technique.

### DETAILED DESCRIPTION OF THE INVENTION

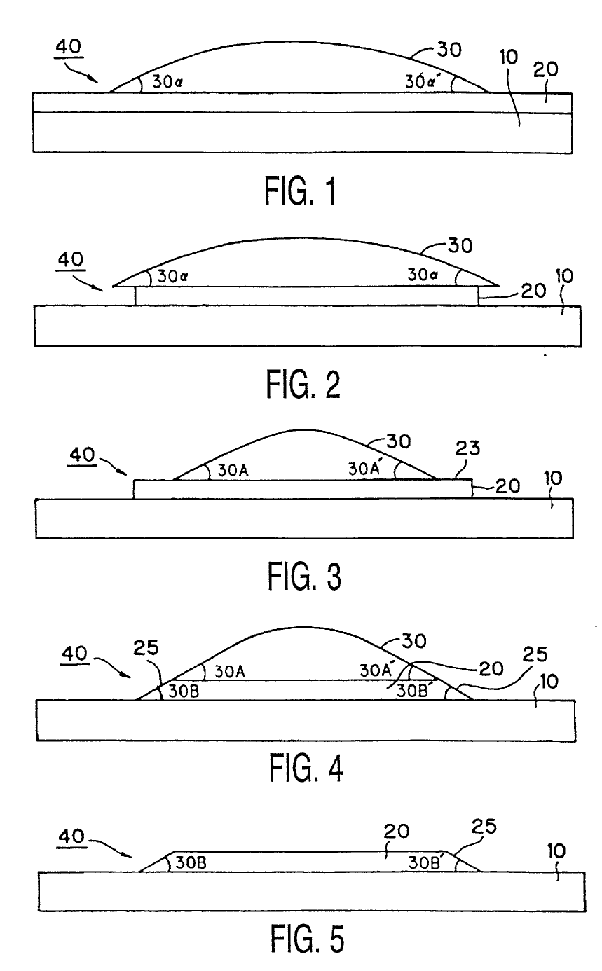

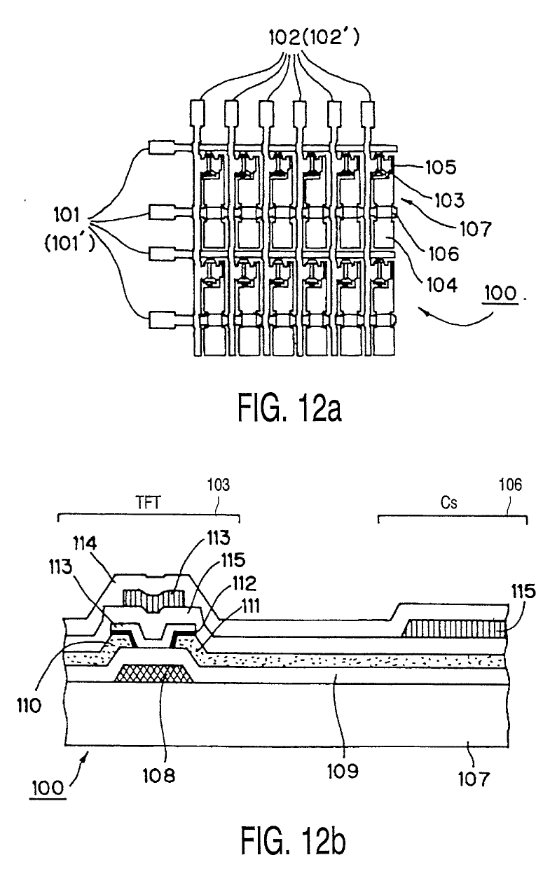

Following will explain in detail a method of producing the metal light shutter film (see FIG. 12 (b)) for the TFT used in the top-gate type of active matrix LCD with references to FIG. 1 through FIG. 11 as an example of the fine production work for metal films in conjunction with the embodiment of the invention. It should be noted that although a plurality of metal light shutter films are actually formed respectively for each of the TFTs on the glass substrate 1, only one metal light shutter film formed upon one TFT is described hereinafter for the illustration purpose.

(I) Main Processes in the Inventive Production Method (see FIG. 1 to FIG. 5)

(1) Process for Forming a Metal Film (Mo—Cr Film) and a Resist Pattern (FIG. 1)

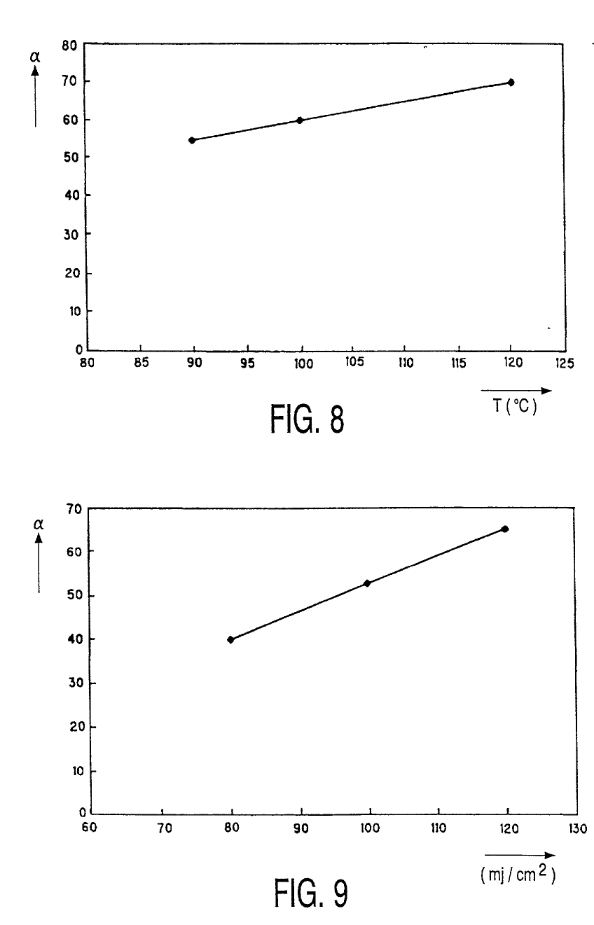

FIG. 1 illustrates a process for depositing a metal film 20 of Mo—Cr (containing Mo as its primary gradient) on a glass substrate 10 by means of sputtering or vacuum deposition method and then forming a resist film 30 on the metal film 20 wherein the glass substrate 10 might have been cleaned with a spin scrubbing method and dried up with a spin drier. The resist film herein may be a positive resist that is commonly used. The resist film is coated on the Mo—Cr film with about 80 nm thickness by means of, for example, a spin coater, so as to be formed about 1.3 μm thick. The resist film is then pre-baked with a hot plate and receives a development process with a spin development or a puddle development after an exposure process by means of an exposure equipment such as a stepper. The resist film is further washed with water and spin-dried up and finally post-baked using the hot plate. As a result, such resist film 30 is obtained as illustrated in FIG. 1, which has been patterned approximately in an arc shape in terms of a cross-sectional view, having both taper angles 30α, 30α′ in a range of about 30 to 50 degrees and a pattern dimension of 10 μm depth and 35 μm width. Following will further explain a production method for forming the smaller (or more gentle) taper angles 30α, 30α′ as above-described, in conjunction with FIG. 8 through 11. The advantage in obtaining such gentle taper angles α will be explained below in conjunction with the section (4) “Taper dry-etching for the Mo—Cr metal film”.

Conditional parameters in forming the resist 30 include mainly the number of spinning rotations, the resist pre-baking temperature, the resist exposure amount by the exposure equipment, the development duration time and the resist post-baking temperature. Since the number of spinning rotations determines the initial thickness of the resist film, it is assumed in this embodiment that a specific number of spinning rotations is to be selected so as to gain about 1.3 μm thickness.

At first, a method to gain gentle taper angles a with a variation of the resist pre-baking temperature will be described in conjunction with FIG. 8. As described above, the resist film is first pre-baked using a hot plate after the resist deposition but before the exposure when performing a pattern forming process (this process will be simply referred to as “a resist pre-baking process” hereinafter). During this resist pre-baking process, as seen in FIG. 8, the resist taper angles α tend to become more gentle as the temperature for heating the resist film using the hot plate becomes lower. Therefore, it is possible to gain gentle taper angles α by utilizing this tendency. However, because too much lower temperature tends to bring out a too much reduction in the resist film during the subsequent resist development process, about 90 degrees C. of the resist pre-baking temperature may be preferably selected.

Secondly, a method to gain gentle taper angles α with a variation of the resist exposure will be described in conjunction with FIG. 9. The initial film thickness is determined as about 1.3 μm as noted above. As seen in FIG. 9, if the film thickness is around 1 μm, the taper angles 30α, 30α′ tend to become gentle with a less exposure amount (mJ/cm²) than a given optimum amount. Therefore, it is possible to gain gentle taper angles α by utilizing this tendency. In particular, the exposure is performed for 80 seconds by means of a shower. The given optimum exposure amount varies with the film thickness. For example, it is preferably about 70 mJ/cm² in case of 1.2 μm thickness and about 120 mJ/cm² in case of 2.0 μm thickness.

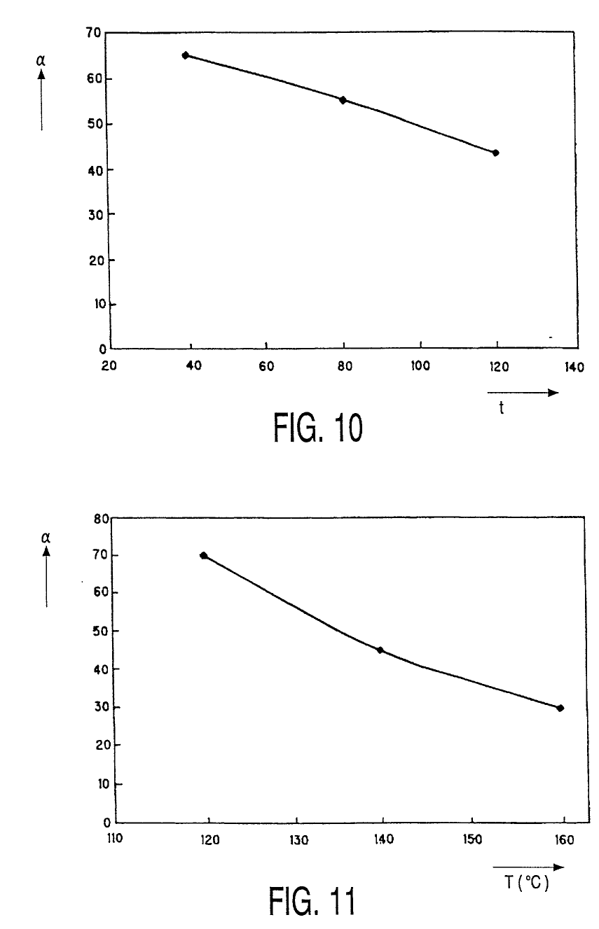

Thirdly, a method to gain gentle taper angles α with a variation of the resist development time will be described in conjunction with FIG. 10. As seen in FIG. 10, the resist taper angles α tend to become more gentle as the time for the resist development becomes longer. Therefore, it is possible to gain gentle taper angles α by utilizing this tendency.

Finally, a method to gain gentle taper angles α with a higher temperature for post-baking the resist will be described in conjunction with FIG. 11. As seen in FIG. 11, the resist taper angles α tend to become more gentle and the resist shape tends to become more flat as the resist post-baking temperature becomes higher. However, too much higher temperature may cause problems including a difficulty in removing the resist after the etching, so about 150 degrees C. may be preferable. In particular, since this method of increasing the resist post-baking temperature is applied in the final stage of the resist forming process, it is possible to finally adjust the finished taper angles α to certain desired angles.

In order to gain gentle taper angles α of the metal film, it may be possible to use either only any one of the above-described four methods or any combination of those four methods. In other words, any one of those four methods or any combination of those four methods may be used with appropriately selected conditions so as to finally gain preferable taper angles α of 30 or less degrees. It should be appreciated that the data shown in the graphs of FIG. 8 through FIG. 10 are only used as examples to illustrate variable tendencies of the resist taper angles when the respective conditional parameters are changed and that values of these conditional parameters should not be limited to the illustrated data.

(2) Wet-Etching Process for Mo—Cr Film (FIG. 2)

FIG. 2 illustrates a wet-etching process for the MoCr film 20 formed through the previous process in conjunction with FIG. 1 so as to remove some portion of MoCr film but leave the MoCr portion that is covered with the resist pattern 30. This wet-etching is performed in such manner that several units contained in a carrier cassette (where one unit 40 comprises a resist film 30, a metal film 20 and a substrate 10 as shown in FIG. 1) are immersed for about 30 seconds into the etchant of mixture liquid of phosphoric acid and nitric acid keeping its temperature in a range between the room temperature and 40 degrees C. The process time is controlled by means of a commonly used etching completion detector. During the wet-etching process, the carrier being immersed into the etchant is oscillated and the carrier cassette is applied bubbles or megasonic particles.

Because the wet-etching process is isotropic, the MoCr metal film 20 is side-etched so that the side of the MoCr metal film 20 is removed up to the area just below the sideline of the resist film 30. As a result, after the completion of the wet-etching, the cross-sectional structure of the resist film 30 and the MoCr film 20 in combination represents a mushroom-like shape. In particular, the resist film 30 is overhanging, like eaves, abut 0.2 μm from the edge portions of the MoCr film 10 as illustrated in FIG. 2. After such shape has been formed, the resist/metal/substrate unit 40 is washed with pure water and then dried up by means of an air knife or a centrifugal drying equipment.

(3) Half Ashing Process for the Resist Film with Oxygen Gas

Each of the resist/metal/substrate unit 40 that has been processed through the above-described wet-etching process is then retrieved from the carrier cassette and stored in a vacuum chamber (not shown) by an appropriate auto conveyer. Within the vacuum chamber (its inside temperature being kept as about 40 degrees C.), the plasmatic oxygen gas is flowed from the upper side of the vacuum chamber toward the resist/metal/substrate unit 40 to apply an ashing process on the resist/metal/substrate unit 40 for about 40 seconds under the ashing pressure of 133 Pa with oxygen in accordance with the RIE method until the portion of the MoCr film 20 that has been located below the sideline of the resist film 30 may be exposed about 0.2 μm. This ashing process will be simply referred to as “a half-ashing process” hereinafter. Note that a higher ashing pressure can further improve the ashing rate. A problem in related with lack of such exposed portion 23 of the Mo—Cr metal film 20 will be addressed in detail in conjunction with the next process.

(4) Taper Dry-Etching Process for the Mo—Cr Film (FIG. 4)

After the half-ashing process, within the same vacuum chamber (its inside temperature being still kept as about 40 degrees C.), the plasmatic mixed gas of chlorine (Cl₂) and oxygen (O₂) (its mixture ratio of chlorine to oxygen is 2 to 3) is flowed from the upper side of the vacuum chamber toward the resist/metal/substrate unit 40 to apply a dry-etching process on the resist/metal/substrate unit 40 for about 60 seconds under the high frequency electricity of 2.3 kW for the bias in accordance with the same RIE method. As a result, the Mo—Cr film 20 is formed, which has taper potions 25 with taper angles 30B, 30B′ substantially equal to the taper angles 30A, 30A′ (which are approximately equal to the taper angles 30α, 30α′).

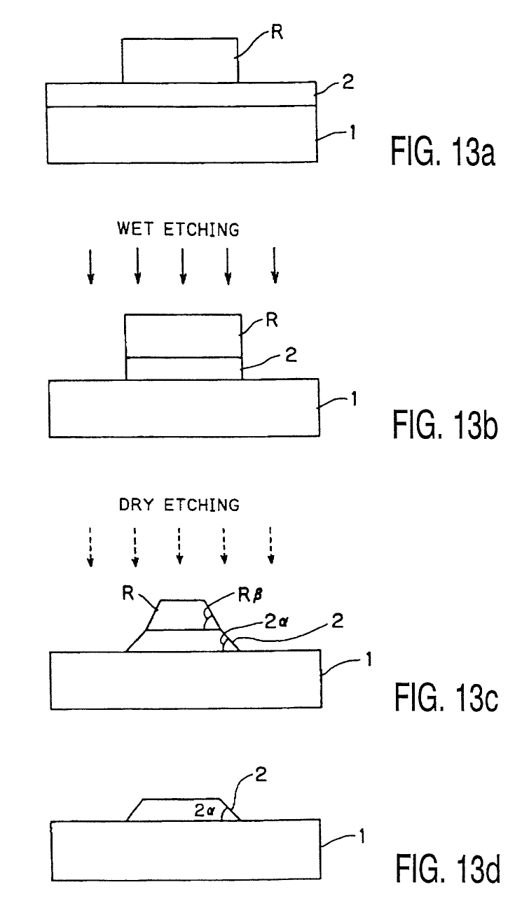

In the following, the problem in related with lack of the exposed portion 23 of the Mo—Cr metal film 20 during the previous process and the advantage of the gentle taper angles will be explained. The first discussion is related with the problem that may be caused by this taper dry-etching process when the exposed portion 23 of the Mo—Cr metal film 20 has not been formed during the previous process. If a dry-etching has been performed on the metal film without such half-ashing process as described above to form the taper angles as shown in FIG. 4, the dry-etching must start with the state in which the metal portion of the Mo—Cr film 20 is not exposed. Thus, almost all time of the dry-etching process, for example, 60 seconds, must be consumed for the setback of the resist film 30 while the Mo—Cr film 20 itself is not etched so much. So, the resulting cross-sectional shape of the Mo—Cr film 20 would be almost same as in the wet-etching process as illustrated in FIG. 13 (c). Accordingly, without the half-ashing process (FIG. 3), the process time would be significantly prolonged because the resist setback speed should be in accordance with the dry-etching condition involving relatively low speed for the Mo—Cr film 20. Such prolonged process time will then cause a prolonged overall process time unnecessarily. Besides, since the dry-etching is essentially anisotropic, an etching in the side direction (side attack) may occur depending on the conditions. Thus, it is difficult to form certain gentle taper angles if the exposed portion 23 of the Mo—Cr film has not been formed in the previous process.

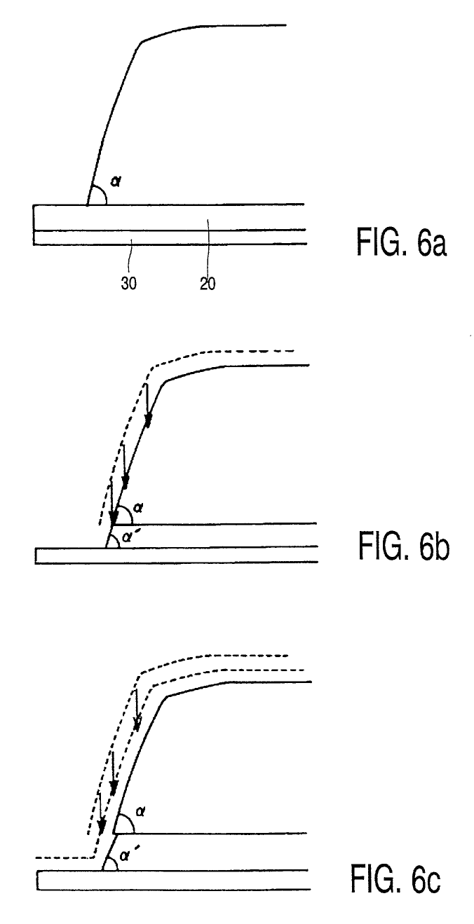

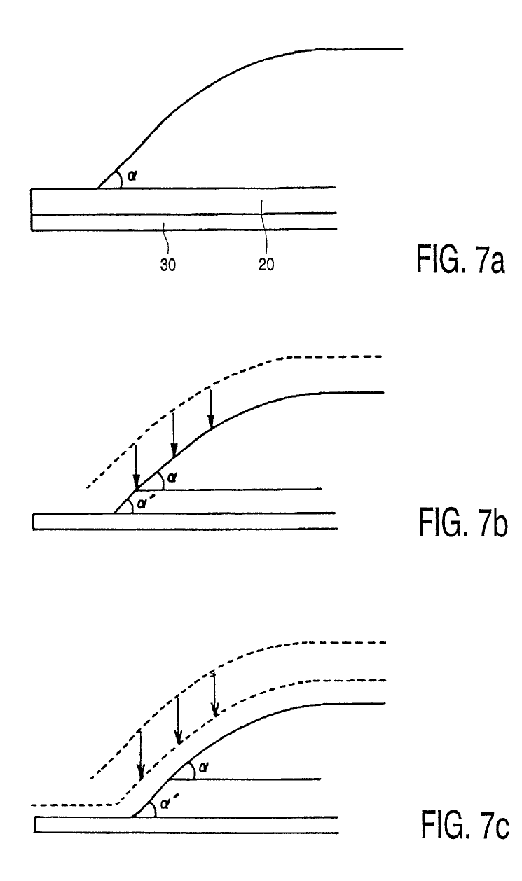

Now referring to FIG. 6 and FIG. 7, the advantage of the gentle taper angles will be explained. FIG. 6 illustrates a dry-etching where the initial resist angles, namely initial taper angles α, are steep. On the other hand, FIG. 7 illustrates a dry-etching where the initial resist angles, namely initial taper angles α, are gentle.

As for the case of the steep initial angles of the taper angles α as illustrated in FIG. 6 (a), assume that the resist taper angles are about 70 degrees. When a dry-etching process using RIE method is performed in this case, the amount of horizontal setback of the resist film is little due to the steep taper angles α, while the etching along the vertical direction will selectively proceed because of anisotropy of the dry-etching process. Thus, the dry-etching process is resulted in producing the metal film having equally steep taper angles α′ with the initial resist taper angles α (about 70 degrees) as illustrated in FIG. 6 (c).

On the other hand, as for the case of the gentle initial angles of the taper angles α as illustrated in FIG. 7(a), assume that the resist taper angles are about 30 degrees. When a dry-etching process using RIE method is performed in this case, the amount of horizontal setback of the resist film is sufficient due to the gentle taper angles a regardless of anisotropy of the dry-etching process. Accordingly, the dry-etching process is resulted in producing the metal film having equally gentle taper angles α′ with the initial resist taper angles α (about 30 degrees) as illustrated in FIG. 7 (c). Thus, the taper angles of about 30 or less degrees may bring out a significant advantage in terms of coverage for all of the layers covering the metal film. For example, when the taper angles a are gentle and accordingly the sidewalls of the metal film 20 close to the horizontal plane, the insulation layer SiOx can be formed thinly along the edge portion of the metal film 20. Thus, it is possible to avoid a so-called step discreteness that may occur at the step portion of the upper layer above the metal film and may cause a problem of dot defects in the displayed pixels of the finished LCDs. It is statistically observed that the taper angles of 30 and less degrees can contribute to a higher yield by 3 to 5 points in comparison with the taper angles of 60 and more degrees.

(5) Resist Removing Process

After the taper dry-etching process on the metal film as explained in the previous section (4), the resist pattern is to be removed using a remover of aminic solution where the process time is about 60 to 90 seconds and the solution temperature is 40 to 60 degrees C. After the removing process and a subsequent, known cleaning/drying process, the Mo—Cr metal film 20 as a light shutter film (108) having taper angles 30B, 30B′ almost equal to the taper angles 30A, 30A′ is formed on the glass substrate 10 as illustrated in FIG. 5.

(II) Variations

It should be understood that the invention claimed in each of the appended claims is not intended to be limited to any of the specific embodiments as described above and may employ any of various embodiments within the scope of each of the appended claims. Such various embodiments include the following:

(1) Although the Mo—Cr metal has been used as an exemplary material for the metal film in the above-described embodiments, any other metal material may be alternatively used. Such other metal materials include pure Mo metal, pure Ti metal, pure Ta metal, an alloy of MO, Ti and Ta, and Mo—W metal. While a dry-etching on the Mo—Cr metal has been performed by using a mixed gas of chlorine and oxygen, a mixed gas of fluorine and oxygen may be used for the pure MO or Mo—W metal. Such dry-etching with the mixed gas of fluorine and oxygen may obviate any protection action against the corrosion within the dry-etching chamber whereas such protection action has been required in case of the dry-etching with the mixed gas of chlorine and oxygen. This can contribute to decreasing the production cost and produce an advantage of the longer life of the chamber.

(2) In the above-described embodiments, the inventive method has been applied to the metal film as a light shutter film for the top-gate type of the TFT. However, the invention may be also applied to any metal film such as gate bus, drain electrode and source electrode etc, and even for the bottom-gate type of the TFT.

(3) In the above-described embodiments, the inventive method has been applied to the metal film within the TFTs to be especially used for the active matrix type of the LCDs. However, the inventive method may be also applied to any other metal film to be integrated within other thin film devices or semiconductor silicon wafers.

Consequently, as described above, in accordance with the invention, it is possible to constantly produce metal films having certain gentle taper angles to be used within thin film devices. Furthermore, in accordance with the invention, it is possible to significantly improve the production efficiency and the quality of such thin film devices as the TFTs used for the LCDs.

1. A method for producing a metal film, the method comprising:
a first step for depositing a metal film on the surface of a given substrate;
a second step for coating a resist material on the metal film to form a resist film;
a third step for forming a resist pattern of the resist film by means of a photolithographic method;
a fourth step for performing a wet-etching on the portion of the metal film that is not covered by the resist film;
a fifth step for performing an oxygen-ashing on the resist pattern of the resist film;
a sixth step for performing a dry-etching so as to form taper shapes on both end portions of the cross section of the metal film; and
a seventh step for removing the resist pattern,
wherein during the second step the resist film is formed in such way that both end portions of the cross section of the resist film have certain taper angles and during the fifth step the oxygen-ashing on the resist pattern is performed so that the metal film is exposed at both end potions of the cross section of the resist pattern.

2. A method as claimed in claim 1, wherein the given substrate is either an insulation type of substrate comprising glass-like materials or a semiconductor substrate comprising silicon-like materials.

3. A method as claimed in claim 1 or 2, wherein the cross section of the resist film having the certain taper angles on the both end portions is formed approximately in an arc shape with a bow shape at the bottom of the cross section of the resist film.

4. A method as claimed in any of claim 1 to 3, wherein during the second step the both end portions of the resist film are formed so as to have certain taper angles by lowering the temperature for pre-baking to be performed on the resist film to a predetermined degree after having coated the resist film but before the light exposure by the photolithographic method.

5. A method as claimed in any of claim 1 to 3, wherein during the second step the both end portions of the cross section of the resist film are formed so as to have certain taper angles by setting the light exposure amount smaller than an optimal exposure amount at the time of the light exposure.

6. A method as claimed in any of claim 1 to 3, wherein during the second step the both end portions of the cross section of the resist film are formed so as to have certain taper angles by prolonging the resist development time with the photolithographic method.

7. A method as claimed in any of claim 1 to 3, wherein during the second step the both end portions of the cross section of the resist film are formed so as to have certain taper angles by increasing the temperature for post-baking to be performed on the resist film to a predetermined degree after the light exposure on the resist film by the photolithographic method.

8. A method, characterized in that the both end portions of the cross section of the resist film are formed so as to have certain taper angles by any combination of the methods claimed in any of claim 4 to 7.

9. A method as claimed in any of claim 1 to 8, wherein the certain taper angles are about 30 or less degrees.

10. A method as claimed in any of claim 1 to 9, wherein the metal film comprises either Cr metal, Mo metal, Ti metal, Ta metal, W metal or an alloy of any combination of these five kinds of metals.

11. A method as claimed in any of claim 1 to 10, wherein the metal film is a metal film for forming a light shutter film, a gate bus, a drain electrode or a source electrode for a top-gate type of TFT.

12. A method as claimed in any of claim 1 to 10, wherein the metal film is a metal film for forming a gate bus, a drain electrode or a source electrode for a bottom-gate type of TFT.

13. A thin film device comprising the metal film that is claimed in any of claim 1 to 10.

14. An active matrix type of liquid crystal display device device comprising TFTs as active elements wherein the TFT is the thin film device claimed in claim 13.
